(19) United States
(12) Patent Application Publication
(10) Pub. No.: US 2002/0177299 A1
(43) Pub. Date: Nov. 28, 2002

(54) Interconnects with dielectric spacers and method for forming the same

(76) Inventors: Yei-Hsiung Lin, Hsinchu (TW); Cheng-Hui Chung, Hsinchu Hsien (TW); Chen-Chiu Hsue, Hsinchu (TW)

Correspondence Address: BIRCH STEWART KOLASCH & BIRCH, PO BOX 747, FALLS CHURCH, VA, 22040-0747, US

(21) Appl. No.: 09/963,369

(22) Filed: Sep. 27, 2001

(30) Foreign Application Priority Data
May 23, 2001 (TW) 90112361

(51) Int. Cl. H01L 21/4763

(52) U.S. Cl. 438/637

(57) ABSTRACT

A method and a structure of interconnects with dielectric spacers is disclosed. A semiconductor substrate with a plurality of interconnects is provided. A conformal first dielectric layer is formed on the interconnects and the substrate. The first dielectric layer is partially etched back to expose a partial surface of the substrate and the top surface of the interconnects, leaving remaining first dielectric layers on the sides of the interconnects, wherein the remaining first dielectric layers are spacers. A second dielectric layer is formed on the substrate, the spacers and the interconnects, and planarization is performed on the second dielectric layer. Thus, the spacers serve as etching stop layers and/or supporting layers of the interconnects.

### BACKGROUND OF THE INVENTION

1. Field of the Invention

The present invention relates to the semiconductor manufacturing process, and more particularly, to a method for forming interconnects with dielectric spacers and the structure thereof.

2. Description of the Related Art

In the traditional interconnect fabrication process of semiconductor manufacture, silicon oxide is usually used as an inter-metal dielectric (IMD) layer, formed on a metal layer/line. With an increase in integration, misalignment often occurs during photolithography. This causes the inter-metal dielectric (IMD) layer to be over-etched, and causes current leakage to seriously affect device reliability. With the shrinkage of circuits, the collapse of the thinner and weaker metal layer/line also occurs. This also seriously affects device reliability.

To date, studies of misalignment in the interconnect process have only addressed the anti-refraction layer formed on the metal layer. For example, in U.S. Pat. No. 5,580,701, Lur et al disclosed forming an anti-reflection layer between the photoresist and its underlying poly layer. This eliminates the occurrence of standing wave between incident and reflected light. The method disclosed in U.S. Pat. No. 5,580,701 cannot, however, solve the problem mentioned previously.

FIGS. 1a˜1c are schematic views of a traditional interconnect process. FIG. 1a shows a structure of traditional interconnect. The structure comprises a semiconductor substrate 100 whereon a plurality of interconnects 110, 120 are formed, and a silicon oxide layer 130 is formed on the interconnects 110, 120 and the substrate 100, wherein the oxide layer 130 is used as an inter-metal dielectric layer.

In FIG. 1b, a via hole 140 is defined through the dielectric layer 130 to the interconnect 110, if misalignment occurs, over-etching will also occur. This causes the inter-metal dielectric layer 130 to be damaged, and causes the bottom of the via hole 140 to near the substrate 100, creating current leakage.

FIG. 1c shows how the shrinkage of metal lines can cause the collapse of the thinner and weaker interconnects. The foregoing disadvantages seriously affect device reliability and yield.

### SUMMARY OF THE INVENTION

In order to solve these problems, a method of forming interconnects with dielectric spacers is provided. A substrate with a plurality of interconnects is provided. A conformal first dielectric layer is formed on the interconnects and the substrate. The first dielectric layer is partially etched back to form spacers on the sides of the interconnects, and a partial surface of the substrate and the top surface of the interconnects is exposed. A second dielectric layer is formed on the substrate, the spacers and the interconnects. The second dielectric layer is formed by planarization, where the spacers serve as etching stop layers or supporting layers of the interconnects.

The structure of interconnects of the invention is also provided. The structure comprises a substrate having a plurality of interconnects, and spacers formed on the sides of the interconnects, where the spacers serve as etching stop layers and/or supporting layers of the interconnects.

The present invention improves on the prior art in that the interconnect structure has dielectric spacers, and the spacers serve as etching stop layers and/or supporting layers. Thus, the invention can decrease current leakage when photolithography encounters misalignment, raises reliability and yield, achieves the goal of IC shrinkage, and ameliorates the disadvantages of prior art.

### BRIEF DESCRIPTION OF THE DRAWINGS

The present invention can be more fully understood by reading the subsequent detailed description in conjunction with the examples and references made of the accompanying drawings, wherein:

FIG. 1a is a schematic view of the interconnect structure of the prior art;

FIGS. 1b˜1c are schematic views of the interconnect structure of the prior art;

FIGS. 2˜6 are sectional diagrams of embodiments of the present invention;

FIG. 7 is a schematic view of an embodiment of the present invention in which misalignment occurs;

FIG. 8 is a sectional view of interconnects with dielectric spacers;

### DETAILED DESCRIPTION OF THE PREFERRED EMBODIMENT

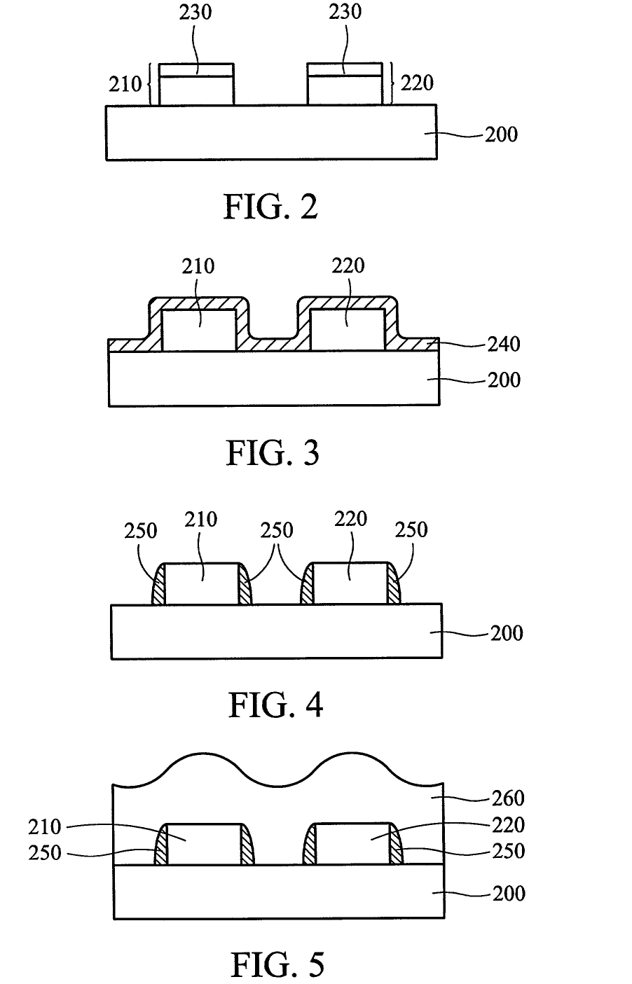

FIGS. 2˜6 are sectional diagrams of embodiments of the present invention.

FIG. 2 shows an embodiment of the present invention relating to the formation of dielectric spacers on the sides of interconnects. A plurality of interconnects 210, 220 are formed on a substrate 200. The interconnects 210, 220 may be, for example, Al, Cu, or AlSiCu alloy formed by deposition. At least one anti-reflection layer 230, such as Ti/TiN or SiON layer, is formed on the interconnects 210, 220. The interconnects 210, 220 include the anti-reflection layer 230. In order to simplify the illustration, the anti-reflection layer 230 is not shown in FIGS. 3˜6.

FIG. 3 shows a conformal first dielectric layer 240 formed on the interconnects 210, 220 and the substrate 200. The first dielectric layer 240 is an insulator material formed by deposition, for example, silicon nitride or silicon oxynitride. The thickness of the first dielectric layer 240 is between about 50 to 300 Å.

FIG. 4 shows the first dielectric layer 240 is partially etched back to expose a partial surface of the substrate 200 and the top surface of the interconnects 210, 220. Moreover, the first dielectric layer 240 remains on the sides of interconnects 210, 220, acting as spacers 250. The spacers 250 serve as etching stop layers or supporting layers of the interconnects 210, 220. The method of partial etching back may, for example, use CF₄ or NF₃ as gas plasma.

In FIG. 5, a second dielectric layer 260 is formed on the substrate 200, the spacers 250 and the interconnects 210, 220. The second dielectric layer 260 may be, for example, a silicon oxide layer formed by deposition. The spacers 250 serve as stop layers in the subsequent via etching process, and/or supporting layers of the interconnects 210, 220. The selective etching rate of the second dielectric layer 260 is greater than 10 times the selective etching rate of the first dielectric layer 240.

In FIG. 6, planarization is performed on the second dielectric layer 260 to smooth the surface, using, for example, CMP or etching.

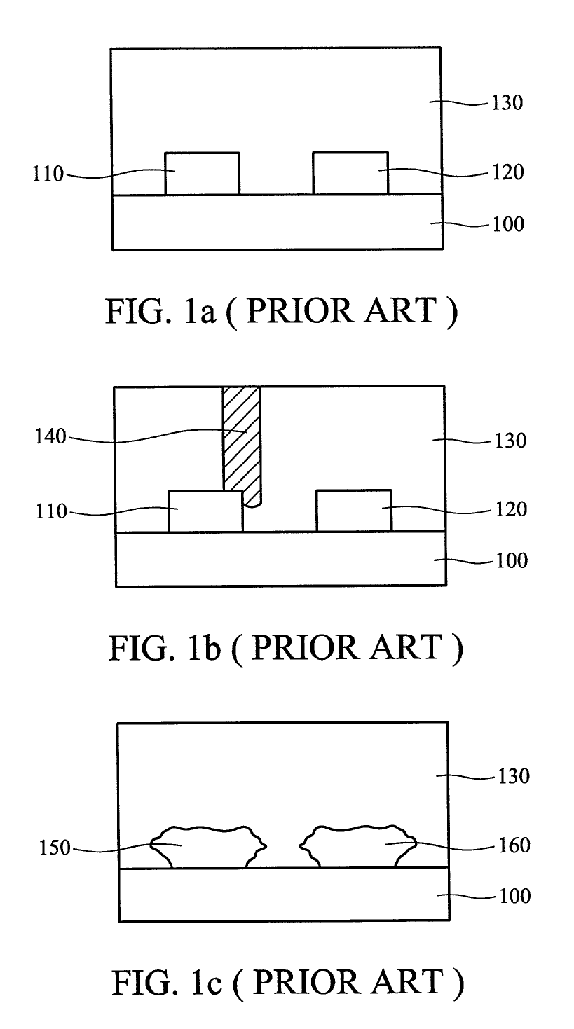

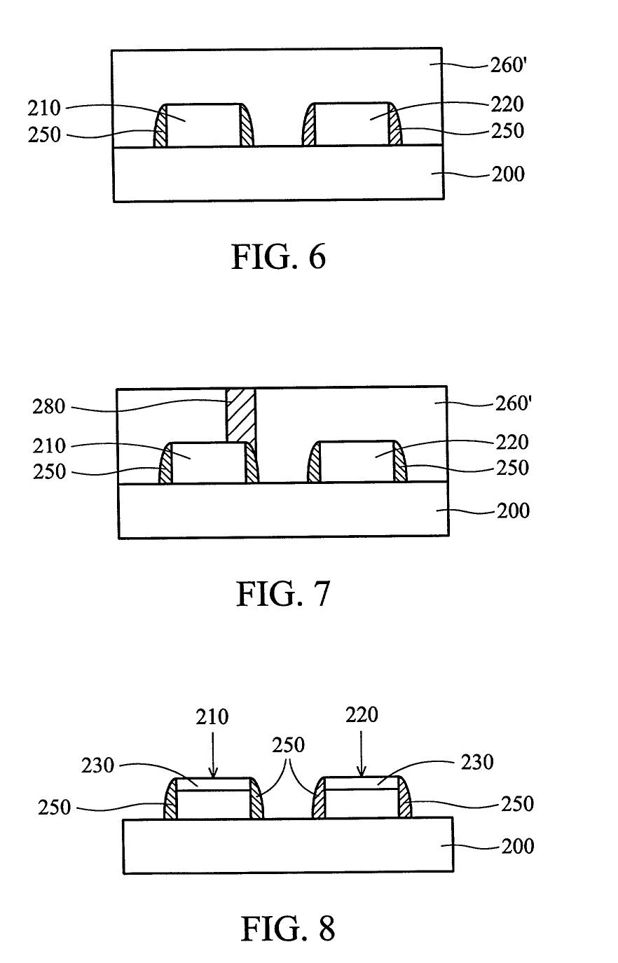

FIG. 7 is a schematic view of an embodiment of the present invention experiencing misalignment. When defining at least one via hole 280, if misalignment occurs, because the spacers 250 of the present invention are used as etching stop layers, the bottom of the via hole 280 will stop at the upper surface of the spacers 250. The via hole 280 is not as shown in the FIG. 1b that damages the dielectric layer 260′. Consequently, the present invention improves the reliability of product and enhances the endurance for misalignment of photolithography.

FIG. 8 shows a structure of interconnects with dielectric spacers. A substrate 200 having a plurality of interconnects 210, 220 is provided. Spacers 250 are on the sides of the interconnects 210, 220. The spacers 250 serve as etching stop layers and/or supporting layers of the interconnects 210, 220. The interconnects 210, 220 further include at least one anti-reflection layer 230. Interconnects 210,220 may be, for example, Al, Cu, or AlSiCu alloy. Anti-reflection layer 230 may be, for example, Ti/TiN or SiON. Spacers 250 maybe, for example, SiN or SiON.

Thus, the present invention provides a method and structure for the formation of interconnects with dielectric spacers, and the spacers serve as etching stop layers and/or supporting layers. The present invention significantly decreases current leakage and improves the reliability of the product. Additionally, the present invention enhances resistance to the effects of misalignment, achieving the goal of IC shrinkage.

Finally, while the invention has been described by way of example and in terms of the above preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method of manufacturing interconnects with dielectric spacers, comprising the steps of:
providing a substrate having a plurality of interconnects;
forming a conformal first dielectric layer on the interconnects and the substrate;
partially etching back the first dielectric layer to expose a partial surface of the substrate and the top surface of the interconnects, leaving remaining first dielectric layers on the sides of the interconnects, wherein the remaining first dielectric layers are spacers;
forming a second dielectric layer on the substrate, the spacers and the interconnects; and
performing planarization on the second dielectric layer using the spacers as etching stop layers and supporting layers.

2. The method according to claim 1, wherein the etching rate of the second dielectric layer is greater than 10 times the etching rate of the first dielectric layer.

3. The method according to claim 1, wherein on the top surface of the interconnects, at least one further anti-reflection layer is formed.

4.The method according to claim 1, wherein the interconnects are selected from the group consisting of Al interconnects, Cu interconnects and AlSiCu alloy interconnects formed by deposition.

5. The method according to claim 1, wherein the first dielectric layer is selected from the group consisting of silicon nitride layer and silicon oxynitride layer formed by deposition.

6. The method according to claim 1, wherein the second dielectric layer is a silicon oxide layer formed by deposition.

7. The method according to claim 3, wherein the anti-reflection layer is selected from the group consisting of Ti/TiN layer and SiON layer formed by deposition.

8. A structure of interconnects with dielectric spacers, comprising:
a substrate having a plurality of interconnects; and
spacers formed on the sides of the interconnects with the spacers serving as etching stop layers and supporting layers for the interconnects.

9.The structure according to claim 8, wherein the material of the interconnects is selected from the group consisting of Al, Cu, and AlSiCu alloy.

10.The structure according to claim 8, wherein the material of the spacers is selected from the group consisting of silicon nitride and silicon oxynitride.

11. The structure according to claim 8, wherein on the top surface of the interconnects, further comprising at least one anti-reflection layer.

12. The structure according to claim 11, wherein the material of the anti-reflection layer is selected from the group consisting of Ti/TiN and SiON.
